(19) United States
(12) Patent Application Publication
(10) Pub. No.: US 2006/0196766 A1
(43) Pub. Date: Sep. 7, 2006

(54) PLASMA DEPOSITION APPARATUS AND METHOD

(76) Inventor: Ga-Lane Chen, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,366

(22) Filed: Dec. 26, 2005

(30) Foreign Application Priority Data
Jan. 5, 2005 (CN) 200510032719.4

(51) Int. Cl. C23C 14/00

(52) U.S. Cl. 204/192.11; 204/298.16

(57) ABSTRACT

The present invention relates to a plasma deposition apparatus and method for forming a thin film on a work piece (41). The deposition apparatus (30) includes a reaction chamber (31), a magnetic device (32,33), a microwave device, two sputtering targets (36), and a substrate holder (40). The reaction chamber includes at least one reaction gas inlet for introducing corresponding at least one reaction gas therethrough and a vacuum system. The reaction chamber has a predetermined plasma generation region. The magnetic device is configured for producing a magnetic field around the plasma generation region. The two sputtering targets are disposed at opposite sides of the plasma generation region and the sputtering targets facing each other. The substrate holder is for securing a work piece thereon. The microwave is in an enough frequency that matches the strength of the magnetic field for conducting electron cyclotron resonance (ECR) in the position and producing plasma with high density in the reaction chamber. Therefore, ions of the plasma bombard the sputtering targets and sputter the target atoms to deposit on the work piece for forming a thin film.

### FIELD OF THE INVENTION

The present invention relates to a thin film deposition apparatus and method, and more specifically, to a plasma deposition apparatus and method which utilize electron cyclotron resonance (ECR) to increase a density of plasma to form a thin film.

### DESCRIPTION OF RELATED ART

Plasma is the forth state of matter. Plasma is a collection of ionized gas consisting of free electrons and ions. Energy needs to be provided for dislodging electrons from atoms/molecules thereby forming the plasma. The energy can be of various forms: e.g. heat energy, electrical energy, or light energy. The plasma can be used in numerous applications such as thin film deposition, plasma based lighting systems, plasma spray and display systems, etc.

Typical methods for producing low temperature plasma include a direct current glow discharge method, a radio frequency glow discharge method and a microwave discharge method. As regards direct current glow discharge method, an electrical discharge is first created between two electrodes in a reaction chamber and plasma support gases are filled in the reaction chamber for producing plasma. The related DCGD apparatus has a simple structure and low cost. However, the ionization degree of the gas is low. The electrodes are apt to be damaged after repeated use. As regards radio frequency glow discharge method, an electromagnetic wave of a radio frequency of about 13.56 MHz is used to form plasma. However, the resultant plasma is only suitable for use in a chemical vapor deposition process. As regards microwave discharge method, microwave energy is introduced into a plasma formation chamber via a waveguide tube or an antenna. Some gas atoms/molecules are activated by the microwave to collide with other gas atoms/molecules in the plasma formation chamber. The collided gas atoms are ionized thereby forming plasma. The microwave discharge method can produce high-density plasma, it is therefore used popularly than other two methods.

FIG. 3 shows a conventional plasma deposition apparatus that is capable of producing high density plasma by means of electron cyclotron resonance (ECR). The plasma deposition apparatus includes a plasma generation chamber 1, a specimen chamber 2 and a microwave-introducing window 3. A magnetron (not shown) is utilized as a microwave source for generating microwave of a frequency of 2.45 GHz. The microwave is introduced via a rectangular waveguide 4 through the microwave window 3 into the plasma generation chamber 1. A plasma extraction window 5 is opposite to the microwave window 3. The plasma 6 thus flows from the plasma generation chamber 1 toward a specimen substrate 7 placed on a specimen table 8. The specimen chamber 2 is in communication with a vacuum system 9. The vacuum system 9 comprises a control valve. Magnetic coils 10 are provided and surround the plasma generation chamber 1. The microwave is set at a frequency of 2.45 GHz, and the magnetic flux density is set at 875 G thereby effecting an electron cyclotron resonance. In addition, the magnetic coils 10 are so arranged that the magnetic field produced thereby not only serves to cause the electron cyclotron resonance in the plasma generation chamber 1 but also goes into the specimen chamber 2. That is, the magnetic field serves to form a divergent magnetic field so that the intensity of the magnetic field in the specimen chamber 2 is gradually decreased from the plasma extraction window 5 toward the specimen table 8. Consequently, the magnetic field also serves to direct the plasma 6 to flow from the plasma generation chamber 1 to the specimen table 8.

A first gas introduction system 12 is provided for introducing gases such as Ar, N2, O2, H2 or the like into the plasma generation chamber 1 for forming the plasma. A second gas introduction system 13 is provided for introducing a raw material gas such as SiH4, N2, O2 into the specimen chamber 2. In order to cool the plasma formation chamber 1, cooling water is introduced to wall portions of the plasma generation chamber 1 through a cooling water inlet 14 and discharged through a cooling water outlet 15. A ring-shaped sputtering target 16 made of a sputtering material such as Al, Mo, Ta or Nb is disposed in the vicinity of the plasma extraction window 5 within the specimen chamber 2 in such a way that the ring-shaped sputtering target 16 surrounds or is in contact with the plasma 6. The target 16 is attached to a target electrode 17. The target 16 is surrounded by a shield electrode 18. The target electrode 17 is connected to a sputtering power supply 19 which may be, for instance, a DC power supply. A water-cooling system (not shown) for cooling the target electrode 17 may be provided. The problem of this kind plasma deposition apparatus is that the activated ions have not enough kinetic energy. As a result, it is not suitable for forming a crystalline thin film.

Another conventional plasma deposition apparatus uses electron cyclotron resonance chemical vapor deposition (ECR CVD) method, therefore capable of forming a film, e.g., a diamond or diamond-like film can be formed. The problem of this kind plasma deposition apparatus is that the raw sputtering materials are limited to be in a form of gas (such as CH4 and C2H5). The material having a high melting point, such as metal and metal oxide, cannot be used as the raw materials for forming thin films. Therefore, The available raw sputtering materials are limited. Such plasma deposition apparatus can only be suitable for depositing Si, or C thin films.

In consideration of the problems of the conventional methods, what is needed is a plasma enhanced deposition apparatus and method that are suitable for depositing various crystalline thin films.

### SUMMARY OF INVENTION

In a preferred embodiment, a deposition apparatus includes a reaction chamber, a magnetic device, a microwave source, two sputtering targets and a substrate holder. The reaction chamber includes at least one reaction gas inlet for introducing corresponding at least one reaction gas therethrough and a vacuum system. The reaction chamber has a predetermined plasma generation region. The magnetic device is configured for producing a magnetic field around the plasma generation region. The two sputtering targets are disposed at opposite sides of the plasma generation region and the sputtering targets facing each other. The substrate holder is for securing a work piece thereon. The frequency of the microwave is matched with the strength of the magnetic field and sufficient to cause electron cyclotron resonance (ECR) in the reaction chamber to form plasma. Then the plasma bombard the sputtering targets and sputter the target atoms to deposit on the work piece to form a thin film. Preferably, the gas pressure of the reaction chamber is in the range from 0.1 to 10 torr. The frequency of the microwave is set about 2.45 GHz and the matched magnetic strength is set about 875 Gauss. The plasma density reaches to the range between 5×1010 cm−3 and 9×1012 cm−3. The substrate holder is rotatable along a central axis associated therewith to improve the thickness uniformity of the thin film.

The present invention also provides a deposition method. The deposition method comprises the following steps: (1) introducing at least one reaction gas into a reaction chamber, the reaction chamber having a predetermined plasma generation region; (2) disposing two sputtering targets at opposite sides of a plasma generation region, the sputtering targets facing each other; (3) supplying a microwave into the reaction chamber; (4) establishing a magnetic field in the reaction chamber, a strength of the magnetic field being configured to be sufficient to effect an electron cyclotron resonance (ECR) in the reaction chamber such that reaction gas plasma is formed in the plasma generation region, whereby the reaction gas plasma bombards the sputtering targets such that target atoms of the sputtering targets are dislodged and deposited on a workpiece.

Comparing to the prior art, the present invention has a higher density of the plasma in the range from 5×1010 cm−3 to 9×1012 cm−3 (ordinary density of the plasma is in the range from 1×109 cm−3 to 9×1010 cm−3), so that the sputtered atoms from the sputtering targets have higher kinetic energy to form high quality crystalline thin film. Comparing to ECR CVD method only suitable for easy gasified raw materials, the present invention is suitable for various sputtering raw materials, such as metal, metal oxide, silicon, silicon oxide, carbon and carbon oxide to deposit various thin films.

Other advantages and novel features of the present invention will become more apparent from the following detailed description of preferred embodiments when taken in conjunction with the accompanying drawings.

### BRIEF DESCRIPTION OF DRAWINGS

Many aspects of the present plasma deposition apparatus and method can be better understood with reference to the following drawings. The components in the drawings are not necessarily to scale, the emphasis instead being placed upon clearly illustrating the principles of the present plasma deposition apparatus and method.

FIG. 1 is a schematic, partially cross-sectional view of a plasma deposition apparatus according to a preferred embodiment; and

FIG. 2 is a flowchart of a deposition method according to another preferred embodiment.

FIG. 3 is a schematic, cross-sectional view of a conventional plasma deposition apparatus;

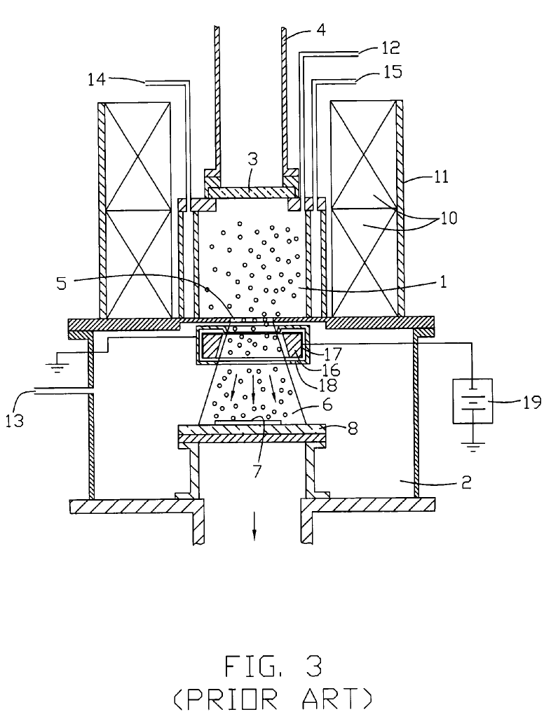

Corresponding reference characters indicate corresponding parts throughout the several views. The exemplifications set out herein illustrate at least one preferred embodiment of the present invention, in one form, and such exemplifications are not to be construed as limiting the scope of the invention in any manner.

### DETAILED DESCRIPTION

Reference will now be made to the drawings to describe embodiments of the present invention, in detail.

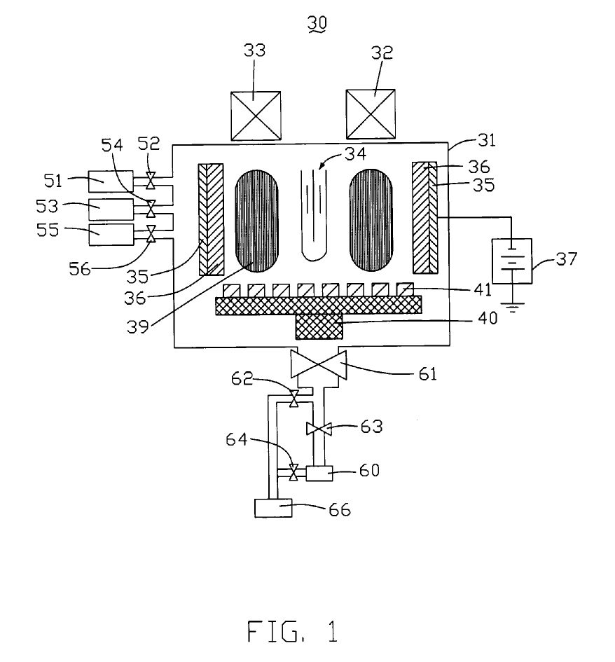

Referring to FIG. 1, a plasma enhanced deposition apparatus 30 comprises an reaction chamber 31, a plurality of mass flow controllers 52,54,56, a turbo pump 60, a rough pump 66, four valves 61,62,63,64, two magnetic coils 32,33, an antenna 34, two sputtering targets 36, two cathodes 36, a DC power supply 37 and a substrate holder 40.

The reaction chamber 31 includes a plasma generation region 39 where a dense plasma is generated. A plurality of reaction gas containers 51, 53, 55 is connected to the reaction chamber 31. The mass flow controllers 52,54,56 are for controlling flow rates of the reaction gases. In the illustrated exemplary embodiment, the reaction gas container 51 contains one of Ar, Kr and Xe. The reaction gas container 53 contains a combination of Ar and N2. The reaction gas container 55 contains one of a combination of Ar and H2, a combination of Ar and CH4 and a combination of Ar and C2H6. The reaction chamber 31 is generally evacuated to obtain a pressure of under about 2×10−6 torr). The valves 61,62,63,64 are arranged between the reaction chamber 31 and the pumps 60,66 for controlling the pressure of the reaction chamber 31.

As shown in FIG. 1, the magnetic coils 32,33 are positioned outside the reaction chamber 31 and are coupled to a direct current power source (not shown). The magnet coils 32,33 are provided for generating a substantially constant magnetic field around the plasma formation region 39. The magnet coils 32,33 generally generate a magnetic field of up to about 875 gauss. Alternatively, the magnetic coils 32,33 can also be positioned inside the reaction chamber 31 if they are cleansed sufficiently for avoiding contaminating sputtered target atoms.

The antenna 34 is positioned in the middle of the reaction chamber 31. The antenna 34 is connected to a microwave source (not shown). The microwave source is for supplying a microwave of a frequency of about 2.45 GHz to the plasma generation region 39 via the antenna 34. The sputtering targets 36 are disposed at opposite sides of the plasma generation region 39. The sputtering targets 36 are electrically connected to cathodes 35, respectively. The sputtering targets 36 may be made of metal, metal oxide, silicon, silicon oxide, carbon, carbon oxide and etc. The cathodes 35 are electrically connected with negative poles of the DC power supplies 37 (only one is illustrated) with a maximum voltage of 1,000 V and a maximum current of 1 A. The positive poles of the DC power supplies 37 are grounded. Consequently, potential risks of abnormal discharge such as spark-over of the sputtering target 36 or undesired ion incidence to the sputtering target 36 may be effectively minimized or even eliminated. The substrate holder 40 is disposed around the underside of the plasma generation region 39. A plurality of work pieces 41 is held on the substrate holder 40.

In operation,, the reaction chamber 31 is initially evacuated by the rough pump 66. The reaction chamber 31 is then evacuated to obtain a pressure of below about 2×10−6 torr by the turbo pumps 60. The reaction gases 51,53,55 are then introduced into the reaction chamber 31 with a gas pressure thereof being maintained in the range from about 0.1 to 10 torr. The magnetic coils 32,33 are powered so as to produce a magnetic field of about 875 Gauss. The reaction gases are then activated to release electrons. Thus, the plasma is generated. The microwave source (not shown) is powered to supply a microwave of about 2.45 GHz into the plasma generation region 39. The released electrons, i.e. free electrons, move along circular orbits associated therewith under the magnetic field. Electron cyclotron resonance (ECR) occurs when the electron cyclotron frequency is equal to the microwave frequency. The energy of microwave is then transferred to the free electrons, which, in turn, cause the reaction gases to be rapidly formed into the plasma. A density of the plasma is generally in the range from 5×1010 cm−3 to 9×1012 cm−3. The plasma bombards the sputtering targets 36 so as to dislodge the target atoms. The dislodged atoms are gradually deposited on the work pieces 41 such that a thin film is formed. Because the plasma has high density and high kinetic energy, it is easy to deposit crystalline thin film on the workpiece. In addition, by the rotation of the substrate holder 40, a uniform thickness of thin film may be achieved.

In another exemplary embodiment, more additional magnetic coils can be provided thereby producing a more strong magnetic field at the plasma generation region, in order to speed up the deposition process.

In an alternative embodiment, the cathodes 35 may be replaced by a DC magnetron to attach the sputtering targets. The magnetron is provided for increasing the deposition speed of the thin film. The magnetron is also provided for attracting the second electrons that are produced during the plasma bombards the sputtering targets 36, thereby preventing the second electrons from bombarding the work pieces surface 41.

In other exemplary embodiments, the magnetic coil 32,33 could be positioned at other appropriate places where it could provide enough magnetic field to form the plasma. Permanent magnet could be employed for providing a magnetic field. Antenna 34 could also be placed at other appropriate places where it could provide a microwave that is sufficient to increase the density of the plasma.

By changing different sputtering targets, the plasma enhanced deposition apparatus of the present invention can deposit various thin films, such as Si films, Metal films, Diamond films, Diamond-like films and etc. For example, carbon sputtering target can used to deposit diamond or diamond-like thin films for optical lens dies. Si or metal oxide can be used to deposit Si or metal thin film for semiconductors. The plasma enhanced deposition apparatus is suitable for many kinds of deposition materials, such as metal, metal oxide, silicon, silicon oxide, carbon and carbon oxide.

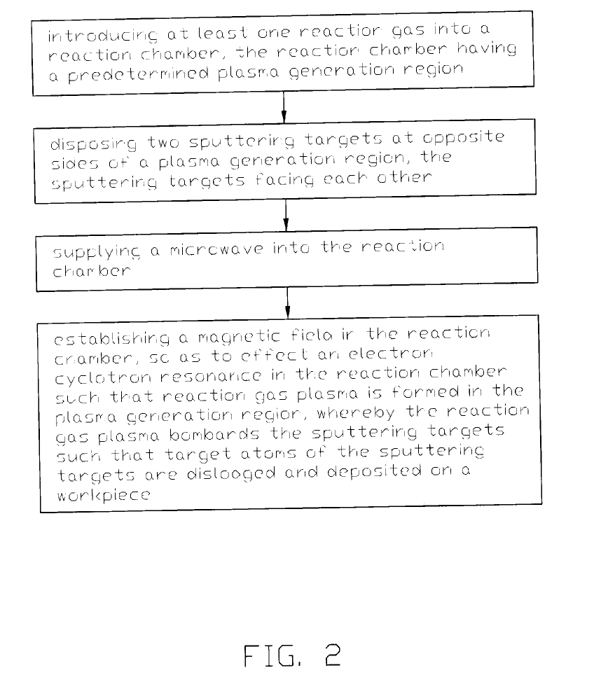

FIG. 2 shows a plasma enhanced deposition method in accordance with the present invention. The method comprises the steps of: introducing at least one reaction gas into a reaction chamber, the reaction chamber having a predetermined plasma generation region; disposing two sputtering targets at opposite sides of a plasma generation region, the sputtering targets facing each other; supplying a microwave into the reaction chamber; establishing a magnetic field in the reaction chamber, a strength of the magnetic field being configured to be sufficient to effect an electron cyclotron resonance (ECR) in the reaction chamber such that reaction gas plasma is formed in the plasma generation region whereby, the reaction gas plasma bombards the sputtering targets such that target atoms of the sputtering targets are dislodged and deposited on a workpiece.

In the above plasma enhanced deposition method, the reactive gases may be selected from the group consisting of Ar, Kr, Xe, H2, CH4, C2H5 and a combination thereof. The pressure of reactive gas in the reaction chamber 31 is advantageously in the range from 0.1 to 10 torr. A frequency of the microwave is set about 2.45 GHz. A strength of the magnetic field is set about 875 Gauss. In the illustrated embodiment, a density of the obtained plasma is generally in the range from 5×1010 cm−3 to 9×1012 cm−3. The deposition materials may be selected from the group consisting of metal, metal oxide, silicon, silicon oxide, carbon and carbon oxide. In addition, the work pieces can be held on the rotating substrate holder for enhancing uniformity of the thickness of the thin film.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A deposition apparatus comprising:
a reaction chamber comprising at least one reaction gas inlet for introducing at least one reaction gas therethrough and a vacuum system, the reaction chamber having a predetermined plasma generation region;
a magnetic device configured for producing a magnetic field around the plasma generation region;
a microwave source for providing a microwave;
two sputtering targets disposed at opposite sides of the plasma generation region, the sputtering targets facing each other; and
a substrate holder for securing a work piece thereon.

2. The plasma enhanced deposition apparatus according to claim 1, wherein the magnetic device includes at least one magnetic coil.

3. The plasma enhanced deposition apparatus according to claim 1, wherein the strength of the magnetic field is set about 875 Gauss.

4. The plasma enhanced deposition apparatus according to claim 1, wherein the microwave source includes a microwave generator and an antenna.

5. The plasma enhanced deposition apparatus according to claim 1, wherein the microwave source is disposed in a middle of the reaction chamber.

6. The plasma enhanced deposition apparatus according to claim 1, wherein the frequency of the microwave from the antenna is set about 2.45 GHz.

7. The plasma enhanced deposition apparatus according to claim 1, further comprising two cathodes with the sputtering targets being attached thereto respectively.

8. The plasma enhanced deposition apparatus according to claim 1, further comprising two magnetrons with the sputtering targets being attached thereto respectively.

9. The plasma enhanced deposition apparatus according to claim 1, wherein the substrate holder is rotatable along a central axis associated therewith.

10. The plasma enhanced deposition apparatus according to claim 1, wherein a gas pressure of the reaction chamber is in the range from 0.1 to 10 torr.

11. A deposition method comprising the steps of:
introducing at least one reaction gas into a reaction chamber, the reaction chamber having a predetermined plasma generation region;
disposing two sputtering targets at opposite sides of a plasma generation region, the sputtering targets facing each other;
supplying a microwave into the reaction chamber; establishing a magnetic field in the reaction chamber, a strength of the magnetic field being configured to be sufficient to effect an electron cyclotron resonance (ECR) in the reaction chamber such that reaction gas plasma is formed in the plasma generation region, whereby the reaction gas plasma bombards the sputtering targets such that target atoms of the sputtering targets are dislodged and deposited on a workpiece.

12. The method according to claim 11, wherein the pressure of reactive gases is in the range from 0.1 to 10 torr.

13. The method according to claim 11, wherein a frequency of the microwave is set about 2.45 GHz.

14. The method according to claim 11, wherein the strength of the magnetic field is set about 875 Gauss.

15. The method according to claim 11, wherein a density of the plasma is in the range from 5×1010 cm−3 to 9×1012 cm−3.

16. The method according to claim 11, wherein the reactive gas is selected from the group consisting of Ar, Kr, Xe, H2, CH4 and C2H5.

17. The method according to claim 11, wherein each of the sputtering targets is connected to a cathode.

18. The method according to claim 17, wherein each of the cathodes is connected to a DC power.

19. The method according to claim 11, wherein each of the sputtering targets is attached to a magnetron.
